(19) United States
(12) Patent Application Publication
(10) Pub. No.: US 2026/0371950 A1
(43) Pub. Date: Nov. 19, 2026

(54) GROUP III NITRIDE SEMICONDUCTOR EPITAXIAL WAFER AND ELECTRONIC DEVICE

(71) Applicant: Panasonic Holdings Corporation, Osaka (JP)

(72) Inventors: Takashi KANO, Shiga (JP); Tomoaki SUMI, Osaka (JP); Yoshio OKAYAMA, Shiga (JP)

(21) Appl. No.: 19/668,254

(22) Filed: May 5, 2026

(30) Foreign Application Priority Data
May 14, 2025 (JP) 2025-081229

(51) Int. Cl. H10P 14/20; C30B 25/18; C30B 29/40; C30B 29/68; H10P 14/24

(52) U.S. Cl. CPC H10P 14/3216; C30B 25/18; C30B 29/403; C30B 29/68; H10P 14/24; H10P 14/2908; H10P 14/3416

(57) ABSTRACT

A Group III nitride semiconductor epitaxial wafer includes: a Group III nitride semiconductor substrate exhibiting N-type conductivity; a first Group III nitride semiconductor film epitaxially grown on the Group III nitride semiconductor substrate, the first Group III nitride semiconductor film containing Al and Ga as Group III elements; and second to Nth Group III nitride semiconductor films epitaxially grown on the first Group III nitride semiconductor film, where Nis a natural number equal to or greater than 2, wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = α Φ {\sum }_{i = 1}^{N} ( {t}_{i} {a}_{i} ) \geq 0$$

where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation

$${C}_{L} \geq {C}_{S} + {C}_{E} = {C}_{S} + α Φ {\sum }_{i = 1}^{N} ( {t}_{i} {a}_{i} ) \geq 0$$

is satisfied.

### CROSS REFERENCE TO RELATED APPLICATION

This application claims a priority of Japanese Patent Application No. 2025-81229 filed on May 14, 2025, the content of which is incorporated herein by reference.

### BACKGROUND OF THE INVENTION

### 1. Field of the Invention

The present disclosure relates to a Group III nitride semiconductor epitaxial wafer having a Group III nitride semiconductor substrate, a first Group III nitride semiconductor film epitaxially grown on the Group III nitride semiconductor substrate, and a second Group III nitride semiconductor film epitaxially grown on the first Group III nitride semiconductor film, and to an electronic device using the Group III nitride semiconductor epitaxial wafer.

### 2. Description of the Related Art

Group III nitride semiconductors are used in fields such as optical devices such as semiconductor lasers and light-emitting diodes, as well as high-frequency or high-power electronic devices. These semiconductors have attracted particular attention in recent years because they are expected to reduce switching losses during power conversion compared to silicon-based devices. In order to fabricate high-frequency or high-power electronic devices, it is necessary to fabricate the devices on high-quality Group III nitride semiconductor substrates that can suppress the occurrence of crystal defects in the device layer.

Methods for producing Group III nitride crystals include, for example, hydride vapor phase epitaxy (hereinafter also referred to as HVPE method), ammonothermal, sodium flux, and oxide vapor phase epitaxy (hereinafter also referred to as OVPE method).

In the HVPE method, which is most often used as a substrate fabrication method, hydrogen halide gas is introduced onto a single Group III source material to generate a Group III element halide gas, and the generated Group III element halide gas is used as a source gas for crystal growth. For example, when growing gallium nitride crystals, HCl gas is introduced into Ga metal to produce gallium chloride (e.g., GaCl) gas, and the gallium chloride-containing gas is used as a Group III source, thereby achieving high-speed growth at 1 mm/h or more. In the HVPE method, it is known that Group III nitride crystals with N-type conductivity can be obtained mainly by adding silicon element to the Group III nitride crystals.

In the OVPE method, an oxide source gas is used to add a high concentration of oxygen element to a Group III nitride crystal to produce the crystal (see, for example, WO2015/053341A1). In this method, a Group III oxide gas is reacted with a nitrogen-containing gas to produce a Group III nitride crystal. The substrate obtained by this method has a low dislocation density of the order of 10⁴ cm⁻², and the OVPE method is one means for obtaining a high-quality Group III nitride crystal.

Also disclosed is a technique for forming a plurality of Group III nitride semiconductor layers having different N-type carrier concentrations on a support substrate (see, for example, JP6237401B2).

However, the present inventors have found that there is a problem in that a Group III nitride semiconductor film epitaxially grown directly on a Group III nitride semiconductor substrate obtained by HVPE method or OVPE method may sometimes fail to achieve sufficient flatness.

### SUMMARY

The present disclosure is intended to solve the above-mentioned problems, and one non-limiting and exemplary embodiments provides a Group III nitride semiconductor epitaxial wafer having a flat outermost surface, which includes a Group III nitride semiconductor film epitaxially grown on a Group III nitride semiconductor substrate.

In one general aspect, the techniques disclosed here feature: a Group III nitride semiconductor epitaxial wafer includes:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = α Φ {\sum }_{i = 1}^{N} ( {t}_{i} {a}_{i} ) \geq 0$$

where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation

$${C}_{L} \geq {C}_{S} + {C}_{E} = {C}_{S} + αΦ {\sum }_{i = 1}^{N} ( {t}_{i} {a}_{i} ) \geq 0$$

is satisfied.

In another general aspect, the techniques disclosed here feature: a Group III nitride semiconductor epitaxial wafer includes:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2, wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = αΦ {\sum }_{i = 1}^{N} {\int }_{0}^{{t}_{i}} {a}_{i} ( t ) dt$$

where i is a natural number from 1 to N; the thickness of the i-th Group III nitride semiconductor film is tᵢ (μm); Al composition ratio relative to all Group III elements in the i-th Group III nitride semiconductor film having a thickness t varies in the range of thickness 0 (μm) to thickness tᵢ (μm) along the thickness direction of the i-th Group III nitride semiconductor film, the function of Al composition ratio is expressed as aᵢ(t) (atom %) with thickness t as a variable; the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation

$${C}_{L} \geq {C}_{S} + {C}_{E} = {C}_{S} + αΦ {\sum }_{i = 1}^{N} {\int }_{0}^{{t}_{i}} {a}_{i} ( t ) dt \geq 0$$

is satisfied.

In another general aspect, the techniques disclosed here feature: an electronic device using the Group III nitride semiconductor epitaxial wafer of any one of the above aspects.

In another general aspect, the techniques disclosed here feature: a method for fabricating a Group III nitride semiconductor epitaxial wafer, includes:
providing a Group III nitride semiconductor substrate exhibiting N-type conductivity;
epitaxially growing a first Group III nitride semiconductor film containing Al and Ga as Group III elements on the Group III nitride semiconductor substrate; and
epitaxially growing second to Nth Group III nitride semiconductor films on the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation

$${C}_{E} = αΦ {\sum }_{i = 1}^{N} ( {t}_{i} {a}_{i} ) \geq 0$$

where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), the first to Nth Group III nitride semiconductor films are epitaxially grown so as to satisfy following equation.

$${C}_{L} \geq {C}_{S} + {C}_{E} = {C}_{S} + αΦ {\sum }_{i = 1}^{N} ( {t}_{i} {a}_{i} ) \geq 0$$

In another general aspect, the techniques disclosed here feature: a method for fabricating a Group III nitride semiconductor epitaxial wafer, includes:
providing a Group III nitride semiconductor substrate exhibiting N-type conductivity;
epitaxially growing a first Group III nitride semiconductor film containing Al and Ga as Group III elements on the Group III nitride semiconductor substrate; and
epitaxially growing second to Nth Group III nitride semiconductor films on the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = αΦ {\sum }_{i = 1}^{N} {\int }_{0}^{{t}_{i}} {a}_{i} ( t ) dt$$

where i is a natural number from 1 to N; the thickness of the i-th Group III nitride semiconductor film is tᵢ (μm); the Al composition ratio relative to all Group III elements in the i-th Group III nitride semiconductor film having a thickness t varies in the range of thickness 0 (μm) to thickness tᵢ (μm) along the thickness direction of the i-th Group III nitride semiconductor film, the function of Al composition ratio is expressed as aᵢ(t) (atom %) with thickness t as a variable; the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), the first to Nth Group III nitride semiconductor films are epitaxially grown so as to satisfy following equation.

$${C}_{L} \geq {C}_{S} + {C}_{E} = {C}_{S} + αΦ {\sum }_{i = 1}^{N} {\int }_{0}^{{t}_{i}} {a}_{i} ( t ) dt \geq 0$$

According to the Group III nitride semiconductor epitaxial wafer according to the present disclosure, by disposing, as an intermediate layer, the first Group III nitride semiconductor film containing Al and Ga as Group III elements, it is possible to ensure flatness of the uppermost surfaces of the second to Nth Group III nitride semiconductor films.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional view showing the cross-sectional structure of a group III nitride semiconductor epitaxial wafer according to a first embodiment;

FIG. 2 is a schematic cross-sectional view showing the amount and depth of warp of a group III nitride semiconductor epitaxial wafer that is warped in a downward convex direction;

FIGS. 3A and 3B are flowcharts of a method for fabricating a Group III nitride semiconductor substrate constituting a Group III nitride semiconductor epitaxial wafer according to the first embodiment;

FIG. 4 is a schematic cross-sectional view showing the cross-sectional structure of a fabrication apparatus for a Group III nitride semiconductor substrate constituting a Group III nitride semiconductor epitaxial wafer according to the first embodiment;

FIG. 5 is Table 1 showing the composition of each layer of Group III nitride semiconductor epitaxial wafers according to Examples 1 to 3, in which first to Nth Group III nitride semiconductor films are epitaxially grown above a Group III nitride semiconductor substrate formed by HVPE;

FIG. 6 is Table 2 showing AFM images of a 3-μm square area and a 30-μm square area of the surface of the Group III nitride semiconductor epitaxial wafers according to Examples 1 to 3, as well as the off-angles and root-mean-square (RMS) roughness values of the Group III nitride semiconductor epitaxial wafers;

FIG. 7 is Table 3 showing the composition of each layer of the Group III nitride semiconductor epitaxial wafers according to Examples 4 to 6, in which first to Nth Group III nitride semiconductor films are epitaxially grown above a Group III nitride semiconductor substrate formed by OVPE;

FIG. 8 is Table 4 showing AFM images of a 3-μm square area and a 30-μm square area of the surface of the Group III nitride semiconductor epitaxial wafers according to Examples 4 to 6, as well as the off-angles and root-mean-square (RMS) roughness values of the Group III nitride semiconductor epitaxial wafers;

FIG. 9A is a schematic cross-sectional view showing the Al composition ratio and thickness of each layer of a group III nitride semiconductor epitaxial wafer according to Example 7;

FIG. 9B is a schematic cross-sectional view showing the Al composition ratio and thickness of each layer of a group III nitride semiconductor epitaxial wafer according to Example 8;

FIG. 9C is a schematic cross-sectional view showing the Al composition ratio and thickness of each layer of a group III nitride semiconductor epitaxial wafer according to Example 9;

FIG. 9D is a schematic cross-sectional view showing the Al composition ratio and thickness of each layer of a group III nitride semiconductor epitaxial wafer according to Example 10;

FIG. 10A is a schematic cross-sectional view showing the Al composition ratio and thickness of each layer of a group III nitride semiconductor epitaxial wafer according to Example 11;

FIG. 10B is a schematic cross-sectional view showing the Al composition ratio and thickness of each layer of a group III nitride semiconductor epitaxial wafer according to Example 12; and

FIG. 10C is a schematic cross-sectional view showing the Al composition ratio and thickness of each layer of a group III nitride semiconductor epitaxial wafer according to Example 13.

### DETAILED DESCRIPTION

### <Background to This Disclosure>

As described above, there is a problem that a Group III nitride semiconductor film epitaxially grown directly on a Group III nitride semiconductor substrate may not have sufficient flatness. The present inventors have obtained findings regarding a first technical feature of the present disclosure, namely that sufficient flatness can be achieved by epitaxially growing one or more Group III nitride semiconductor films containing Al and Ga as Group III elements on a Group III nitride semiconductor substrate.

On the other hand, the present inventors have found a problem that a Group III nitride semiconductor epitaxial wafer in which a first Group III nitride semiconductor film containing Al and Ga is epitaxially grown suffers from a downwardly convex warp due to the difference in lattice constant between GaN and AlN or between GaN and AlGaN.

As a result of extensive research into this problem, the present inventors have found that the amount of warp can be estimated by αΦta, which is obtained by multiplying the product of the film thickness t (μm) of the epitaxially grown Group III nitride semiconductor film, the Al composition ratio a (atom %) relative to all Group III elements, and the diameter Φ of the Group III nitride semiconductor epitaxial wafer by a correction coefficient α, and that the amount of warp can be adjusted to be equal to or less than the upper limit, thereby we have arrived at a second technical feature of the present disclosure.

Aspects of the present disclosure will be described below.

A Group III nitride semiconductor epitaxial wafer according to a first aspect, includes:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = αΦ {\sum }_{i = 1}^{N} ( {t}_{i} {a}_{i} ) \geq 0$$

where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation

$${C}_{L} \geq {C}_{S} + {C}_{E} = {C}_{S} + αΦ {\sum }_{i = 1}^{N} ( {t}_{i} {a}_{i} ) \geq 0$$

is satisfied.

A Group III nitride semiconductor epitaxial wafer according to a second aspect, includes:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2, wherein
when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = αΦ {\sum }_{i = 1}^{N} {\int }_{0}^{{t}_{i}} {a}_{i} ( t ) dt$$

where i is a natural number from 1 to N; the thickness of the i-th Group III nitride semiconductor film is tᵢ (μm); Al composition ratio relative to all Group III elements in the i-th Group III nitride semiconductor film having a thickness t varies in the range of thickness 0 (μm) to thickness tᵢ (μm) along the thickness direction of the i-th Group III nitride semiconductor film, the function of Al composition ratio is expressed as aᵢ(t) (atom %) with thickness t as a variable; the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation

$${C}_{L} \geq {C}_{S} + {C}_{E} = {C}_{S} + αΦ {\sum }_{i = 1}^{N} {\int }_{0}^{{t}_{i}} {a}_{i} ( t ) dt \geq 0$$

is satisfied.

The Group III nitride semiconductor epitaxial wafer according to a third aspect in addition to the first or second aspect, the first Group III nitride semiconductor film may have an Al composition ratio of 0.1 atom % or more in the first Group III nitride semiconductor film.

The Group III nitride semiconductor epitaxial wafer according to a fourth aspect in addition to any one of the first to third aspects, the Group III nitride semiconductor substrate may have a carrier concentration of 10¹⁷ cm⁻³ or more and 10¹⁹ cm⁻³ or less.

The Group III nitride semiconductor epitaxial wafer according to a fifth aspect in addition to any one of the first to third aspects, the Group III nitride semiconductor substrate may have a carrier concentration of 10²⁰ cm⁻³ or more, and wherein the dopant element is oxygen.

The Group III nitride semiconductor epitaxial wafer according to a sixth aspect in addition to any one of the first to fifth aspects, the first Group III nitride semiconductor film may have a carrier concentration of 10¹⁷ cm⁻³ or more.

The Group III nitride semiconductor epitaxial wafer according to a seventh aspect in addition to any one of the first to sixth aspects, an i-th Group III nitride semiconductor film, where i is 2 or more, epitaxially grown above the first Group III nitride semiconductor film may have a carrier concentration of 10¹⁷ cm⁻³ or less.

The Group III nitride semiconductor epitaxial wafer according to a eighth aspect in addition to any one of the first to sixth aspects, the first Group III nitride semiconductor film may have a carrier concentration of 10¹⁷ cm⁻³ or more, and an i-th Group III nitride semiconductor film, where i is 2 or more, epitaxially grown above the first Group III nitride semiconductor film may have a carrier concentration of 10¹⁷ cm⁻³ or less.

An electronic device according to a ninth aspect using the Group III nitride semiconductor epitaxial wafer of any one of the first to eighth aspects.

A method for fabricating a Group III nitride semiconductor epitaxial wafer according to a tenth aspect, includes:
providing a Group III nitride semiconductor substrate exhibiting N-type conductivity;
epitaxially growing a first Group III nitride semiconductor film containing Al and Ga as Group III elements on the Group III nitride semiconductor substrate; and
epitaxially growing second to Nth Group III nitride semiconductor films on the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation

$${C}_{E} = αΦ {\sum }_{i = 1}^{N} ( {t}_{i} {a}_{i} ) \geq 0$$

where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), the first to Nth Group III nitride semiconductor films are epitaxially grown so as to satisfy following equation.

$${C}_{L} \geq {C}_{S} + {C}_{E} = {C}_{S} + αΦ {\sum }_{i = 1}^{N} ( {t}_{i} {a}_{i} ) \geq 0$$

A method for fabricating a Group III nitride semiconductor epitaxial wafer according to an eleventh aspect, includes:
providing a Group III nitride semiconductor substrate exhibiting N-type conductivity;
epitaxially growing a first Group III nitride semiconductor film containing Al and Ga as Group III elements on the Group III nitride semiconductor substrate; and
epitaxially growing second to Nth Group III nitride semiconductor films on the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation,

$${C}_{E} = αΦ {\sum }_{i = 1}^{N} {\int }_{0}^{{t}_{i}} {a}_{i} ( t ) dt$$

where i is a natural number from 1 to N; the thickness of the i-th Group III nitride semiconductor film is tᵢ (μm); the Al composition ratio relative to all Group III elements in the i-th Group III nitride semiconductor film having a thickness t varies in the range of thickness 0 (μm) to thickness tᵢ (μm) along the thickness direction of the i-th Group III nitride semiconductor film, the function of Al composition ratio is expressed as aᵢ(t) (atom %) with thickness t as a variable; the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), the first to Nth Group III nitride semiconductor films are epitaxially grown so as to satisfy following equation.

$${C}_{L} \geq {C}_{S} + {C}_{E} = {C}_{S} + αΦ {\sum }_{i = 1}^{N} {\int }_{0}^{{t}_{i}} {a}_{i} ( t ) dt \geq 0$$

Hereinafter, a group III nitride semiconductor epitaxial wafer and a fabrication method thereof according to embodiments of the present disclosure will be described with reference to the accompanying drawings.

### First Embodiment

### <Group III Nitride Semiconductor Epitaxial Wafer>

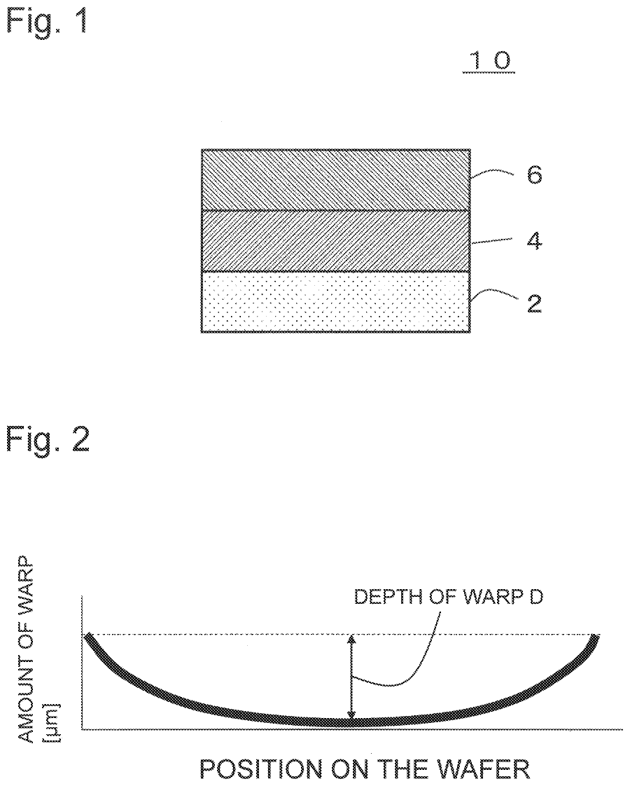

FIG. 1 is a schematic cross-sectional view diagrammatically showing an example of a group III nitride semiconductor epitaxial wafer 10 according to a first embodiment.

The Group III nitride semiconductor epitaxial wafer 10 according to the present disclosure comprises at least three layers: a Group III nitride semiconductor substrate 2, a first Group III nitride semiconductor film 4 including an epitaxial layer epitaxially grown on the Group III nitride semiconductor substrate 2, and a second Group III nitride semiconductor film 6 epitaxially grown on the first Group III nitride semiconductor film 4. The Group III nitride semiconductor substrate 2 exhibits N-type conductivity.

Components constituting this Group III nitride semiconductor epitaxial wafer 10 will be described below.

### <Group III Nitride Semiconductor Substrate>

For example, in order to reduce the on-resistance during operation, the group III nitride semiconductor substrate 2 may be doped with an impurity that serves as an N-type dopant. Then, the group III nitride semiconductor substrate 2 may have N-type conductivity and a carrier concentration of 10²⁰ cm⁻³ or more.

The N-type dopant element of the group III nitride semiconductor substrate 2 may include, for example, at least one element selected from the group consisting of silicon element Si, germanium element Ge, and oxygen element O.

The N-type dopant element of the Group III nitride semiconductor substrate more preferably includes, for example, oxygen element O, which makes it possible to easily add oxygen element to the Group III nitride semiconductor substrate, particularly when the Group III nitride semiconductor substrate to be used as the substrate is fabricated by OVPE method.

When oxygen element is the main N-type dopant element in the Group III nitride semiconductor substrate, the oxygen element may be added at a composition level of, for example, 10²⁰ atoms·cm⁻³ or more, which makes it easy to achieve a carrier concentration of 10²⁰ cm⁻³ or more in the Group III nitride semiconductor substrate.

The Group III nitride semiconductor substrate is not limited to GaN obtained by OVPE method, but may be GaN obtained by HVPE method.

### <First Group III Nitride Semiconductor Film>

The first Group III nitride semiconductor film 4 is a Group III nitride semiconductor film containing Al and Ga as Group III elements, epitaxially grown on the Group III nitride semiconductor substrate 2. When the total amount of Group III elements in the first Group III nitride semiconductor film is taken as 1, the Al composition ratio relative to all Group III elements in the first Group III nitride semiconductor film may be, for example, not less than 0.001 (0.1 atom %) and not more than 0.3 (30 atom %).

The first Group III nitride semiconductor film may have a thickness of, for example, 0.02 μm or more and 1 μm or less.

The thickness of the first Group III nitride semiconductor film is preferably 0.02 μm or more. If the Group III nitride semiconductor film is thinner than 0.02 μm, a sufficiently stable surface is not formed when forming an epitaxial layer on the substrate, and sufficient flatness cannot be obtained.

The thickness of the first Group III nitride semiconductor film is preferably 1 μm or less. If the thickness of the first Group III nitride semiconductor film exceeds 1 μm, the influence of lattice mismatch with the second Group III nitride semiconductor film epitaxially grown on the first Group III nitride semiconductor film may occur.

### <Second to Nth Group III Nitride Semiconductor Films>

Nis a natural number equal to or greater than 2, and the second to Nth Group III nitride semiconductor films may be at least one Group III nitride semiconductor film epitaxially grown sequentially above a Group III nitride semiconductor substrate via the first Group III nitride semiconductor film. Each of the second to Nth Group III nitride semiconductor films may have a thickness of, for example, 1 μm or more and 30 μm or less. By setting the thickness of each of the second to Nth Group III nitride semiconductor films to 1 μm or more, a sufficiently stable surface can be formed when forming an epitaxial layer on the substrate, allowing a device to be formed on the uppermost surface. Furthermore, if the thickness is 30 μm or less, it is easy to maintain the flatness of the epitaxial layer.

It is more preferable that the thickness of each of the second to Nth Group III nitride semiconductor films may be 1 μm or more and 8 μm or less. If the thickness is 1 μm or more and 8 μm or less, a film having a sufficiently stable surface can be formed, and sufficient flatness can be maintained even when the lattice mismatch between the substrate and the epitaxial layer is large.

The epitaxial layers constituting the second to Nth Group III nitride semiconductor films may be one layer, or may have a structure of two or more layers.

The Nth Group III nitride semiconductor film on the outermost surface of the second to Nth Group III nitride semiconductor films has a root mean square (RMS) roughness of 1 nm or less when measured over a 30 μm square area, for example, and has sufficient flatness.

Furthermore, the second to Nth Group III nitride semiconductor films may have a lower Al composition ratio relative to all Group III elements than the first Group III nitride semiconductor film. When the second to Nth Group III nitride semiconductor films each include two or more epitaxial layers, the Al composition ratio may decrease from the film closest to the first Group III nitride semiconductor film toward the upper layers.

Furthermore, when used in electronic devices, it is possible to implement devices with low resistance during operation and low leakage current.

### <Regarding the Warp Amount and Depth of Warp of Group III Nitride Semiconductor Epitaxial Wafer>

FIG. 2 is a schematic cross-sectional view showing the amount and depth of warp of a group III nitride semiconductor epitaxial wafer that has warped in a downward convex direction.

Since the first Group III nitride semiconductor film disposed on the Group III nitride semiconductor substrate contains Al and Ga as Group III elements, downward convex warp occurs in the Group III nitride semiconductor epitaxial wafer due to the difference in lattice constant between GaN and AlN. For example, in a wafer process using a 6-inch Φ (diameter) Si substrate, the downward convex warp of a Si wafer is limited to 60 μm in order to achieve high yields in focusing of a stepper or the like. In other words, as described above, while flatness can be achieved by including Al and Ga as Group III elements in the first Group III nitride semiconductor film, the downward convex warp must be kept within the range of C_{L}, which is the upper limit imposed by the subsequent wafer process. In the subsequent wafer process, devices are formed on the wafer. An upward convex wafer cannot be used in the wafer process.

The amount of downward convex warp (μm) of a Group III nitride semiconductor film formed on a Group III nitride semiconductor substrate is thought to increase in proportion to the wafer diameter Φ (mm), as shown in FIG. 2. We hypothesize the amount of downward convex warp (μm) of a Group III nitride semiconductor film also increases in proportion to the thickness t (μm) of the Group III nitride semiconductor film. Furthermore, we hypothesize the amount of downward convex warp (μm) of a Group III nitride semiconductor film increases in proportion to the Al composition ratio a (atom %) relative to all Group III elements in the Group III nitride semiconductor film.

Considering the above, when first to Nth Group III nitride semiconductor films are disposed on a Group III nitride semiconductor substrate sequentially, it can be assumed that the downward convex warp of each of the first to Nth Group III nitride semiconductor films is expressed by αΦtᵢaⱼ, which is the product of the wafer diameter Φ (mm), the thickness tᵢ (μm) of the i-th Group III nitride semiconductor film, and the Al composition ratio aᵢ(atom %) relative to all Group III elements in the i-th Group III nitride semiconductor film multiplied by a correction coefficient α, where i is a natural number of 1 or more and N or less, N is a natural number equal to or greater than 2.

Furthermore, it can be assumed that the total downward convex warp C_{E} (μm) of the first to Nth Group III nitride semiconductor films is expressed by the sum of the downward convex warp of each Group III nitride semiconductor film. In other words, the total downward convex warp C_{E} (μm) can be calculated using the following formula (1):

$${C}_{E} = α Φ {\sum }_{i = 1}^{N} ( {t}_{i} {a}_{i} ) \geq 0 \qquad ( 1 )$$

where N is a natural number equal to or greater than 2, and i is a natural number of 1 or more and N or less. In addition, since the downward convex direction is shown as positive, the total amount of downward convex warp C_{E} is set to 0 or more.
<When Al Composition Ratio relative to All Group III Elements in Group III Nitride Semiconductor Film Varies in Thickness Direction>

In the above, when the Al composition ratio relative to all Group III elements in the Group III nitride semiconductor film varies in the thickness direction, the function of the Al composition ratio is expressed as a(t) (atom %) with thickness t as a variable in the range of film thickness 0 (μm) to film thickness t (μm) along the film thickness direction of the Group III nitride semiconductor film. In this case, the amount of downward convex warp of the Group III nitride semiconductor film can be assumed to be expressed as following equation.

$$α Φ {\int }_{0}^{t} a ( t ) dt$$

Furthermore, it can be assumed that the total downward convex warp amount C_{E} (μm) of the first to Nth group III nitride semiconductor films is expressed by the total downward convex warp amount of each group III nitride semiconductor film. In other words, the total downward convex warp amount C_{E} (μm) can be expressed by the following formula (2):

$${C}_{E} = α Φ {\sum }_{i = 1}^{N} {\int }_{0}^{{t}_{i}} {a}_{i} ( t ) dt \qquad ( 2 )$$

where N is a natural number equal to or greater than 2, and i is a natural number of 1 or more and N or less. In addition, since the downward convex direction is shown as positive, the total downward convex warp amount C_{E} is set to 0 or more.

The downward convex warp C_{L} (μm), which is the upper limit limited by a wafer process that is a post-process, the downward convex warp amount C_{S} (μm) of the Group III nitride semiconductor substrate, and the total downward convex warp amount C_{E} (μm) of the first to Nth Group III nitride semiconductor films are required to satisfy the relationship expressed by the following formula (3):

C_{L}≥C_{S}+C_{E}≥0 (3)

### <When Al Composition Ratio Is Constant in Group III Nitride Semiconductor Film>

When the Al composition ratio is constant in the group III nitride semiconductor film, the first to Nth group III nitride semiconductor films need to be configured to satisfy the following formula (4) which is a combination of the above formulas (1) and (3):

$${C}_{L} \geq {C}_{S} + {C}_{E} = {C}_{S} + α Φ {\sum }_{i = 1}^{N} ( {t}_{i} {a}_{i} ) \geq 0 \qquad ( 4 )$$

### <When Al Composition Ratio Varies in Thickness Direction in Group III Nitride Semiconductor Film>

When the Al composition ratio varies in the thickness direction in the group III nitride semiconductor film, the first to Nth group III nitride semiconductor films are required to satisfy the following formula (5) which is a combination of the above formulas (2) and (3):

$${C}_{L} \geq {C}_{S} + {C}_{E} = {C}_{S} + α Φ {\sum }_{i = 1}^{N} {\int }_{0}^{{t}_{i}} {a}_{i} ( t ) dt \geq 0 \qquad ( 5 )$$

### <About Correction Coefficient α>

Next, the rough calculation of the correction coefficient α under the following conditions will be described.

As an example, the downward convex warp amount C_{S} of a Group III nitride semiconductor substrate before epitaxial growth of a Group III nitride semiconductor film was 0. When a Group III nitride semiconductor film having a thickness of approx. 3 μm and an Al composition ratio of 3 atom % was disposed on this unwarped 2-inch (diameter Φ50 mm) Group III nitride semiconductor substrate, the downward convex warp C_{S} was 30 μm. Based on the above formula (1), this can be expressed by the following formula (6):

[Warp amount C_{E}]30(μm)=[correction coefficient]α*[wafer diameterΦ]50(mm)*[thickness t]3(μm)*[Al composition ratio a]3(atom %) (6)

From the above formula (6), the correction coefficient α can be estimated to be, for example, 0.067 (mm⁻¹) under the above conditions.

<For 6-Inch (Diameter Φ150 mm) Substrate with Upper Limit of Warp Amount C_{L} of 60 μm>

As an example, when a single layer of a Group III nitride semiconductor film is disposed on a warp-free 6-inch (diameter Φ150 mm, C_{S}=0 μm) Group III nitride semiconductor substrate, the following formula (7) can be established based on the above formulas (3) and (4):

C_{L}>C_{S}+C_{E}=C_{S}+αΦta≥0 (7)

By substituting the above values, the following formula (8) is obtained:

60(μm)≥0.067(mm⁻¹)*150(mm)*ta≥0 6≥ta (8)

In the above example, it can be seen that in order to keep the upper limit of warp amount C_{L} within 60 μm, it is sufficient to dispose a single layer of a Group III nitride semiconductor film having a film thickness t (μm) and Al composition ratio a (atom %) that satisfies the above formula (8) on a warp-free 6-inch (diameter Φ150 mm, C_{S}=0 μm) Group III nitride semiconductor substrate.

### <Electronic Device>

The above-described Group III nitride semiconductor epitaxial wafer may be used in an electronic device. This allows a device with a flat surface, low resistance during operation, and low leakage current to be implemented.

### <Method for Fabricating Group III Nitride Semiconductor Epitaxial Wafer>

The method for fabricating a group III nitride semiconductor epitaxial wafer according to the first embodiment includes, for example, the following steps.
(1) For example, a Group III nitride semiconductor substrate exhibiting N-type conductivity with a carrier concentration of 10²⁰ cm⁻³ or more is formed by OVPE method. Note that a method for fabricating a Group III nitride semiconductor substrate by OVPE method will be described later. Furthermore, the method for forming the Group III nitride semiconductor substrate is not limited to OVPE method, and it may also be formed by HVPE method.
(2) A first Group III nitride semiconductor film containing Al and Ga as Group III elements is epitaxially grown on the Group III nitride semiconductor substrate. The first Group III nitride semiconductor film is, for example, AlGaN. More specifically, when the chemical formula of the first Group III nitride semiconductor film is written as (AlₓGa₁₋ₓ)N, the Al composition ratio x relative to all Group III elements is, for example, 0.001 or more and 0.3 or less. By setting the Al composition ratio x within the above range, sufficient flatness can be obtained for the first Group III nitride semiconductor film, and the occurrence of lattice distortion between the first Group III nitride semiconductor film and the underlying Group III nitride semiconductor substrate can be suppressed.
(3) On the first Group III nitride semiconductor film, second to Nth Group III nitride semiconductor films are epitaxially grown sequentially, where N is a natural number equal to or greater than 2. Since the first Group III nitride semiconductor film has sufficient flatness, the second to Nth Group III nitride semiconductor films can have sufficient flatness, for example, a root mean square RMS roughness value of 1 nm or less over a 30 μm square of the surface.

Furthermore, when the Al composition ratio is constant in each Group III nitride semiconductor film, the first to Nth Group III nitride semiconductor films may be configured to satisfy the above formula (4). When the Al composition ratio varies in each Group III nitride semiconductor film in the thickness direction, the first to Nth Group III nitride semiconductor films may be configured to satisfy the above formula (5).

Thus, the group III nitride semiconductor epitaxial wafer according to the first embodiment can be obtained.

### <Overview of Method for Fabricating Group III Nitride Semiconductor Substrate>

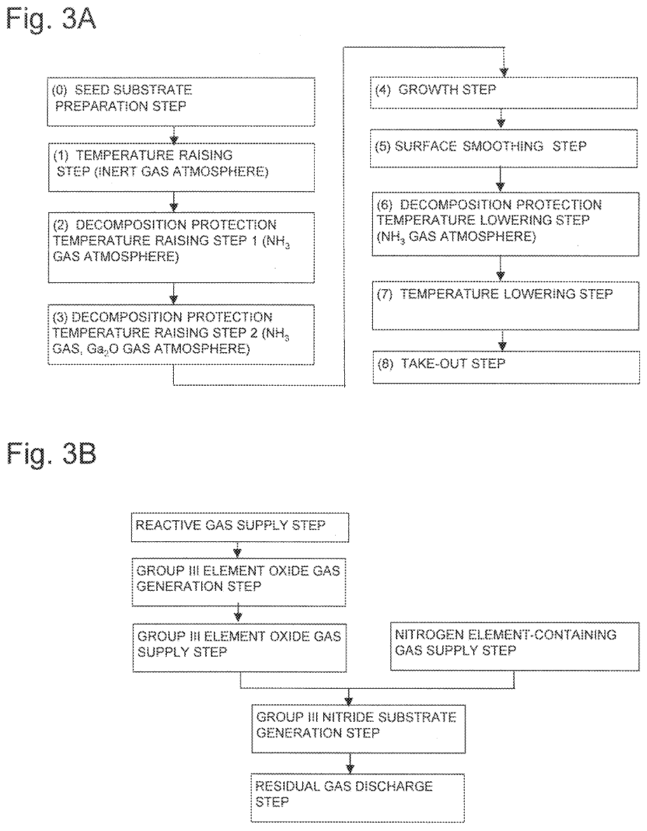

The overview of a method for fabricating a Group III nitride semiconductor substrate constituting a Group III nitride semiconductor epitaxial wafer according to the first embodiment based on the OVPE method will be described with reference to flowcharts of FIGS. 3A and 3B. FIG. 3A shows a chronological flowchart of the fabrication method. FIG. 3B shows, as steps, each functional unit from upstream to downstream in a fabrication apparatus used in this fabrication method.

In a seed substrate preparation step of preparing a seed substrate 116, the seed substrate 116 is placed on a substrate susceptor 117.

In a temperature-raising step, the temperature of a growth chamber 111 is raised to 100 °C or higher and lower than 500 °C in an inert gas atmosphere.

In a decomposition protection temperature-raising step 1, the temperature of the growth chamber 111 is raised to 500 °C or higher and lower than 1100 °C in an NH₃ gas atmosphere.

In a decomposition protection temperature-raising step 2, the temperature of the growth chamber 111 is raised to 1100 °C or higher and lower than 1500 °C in an atmosphere of NH₃ gas and Ga₂O gas.

In a growth step of growing a Group III nitride semiconductor substrate on the seed substrate 116, a Group III element oxide gas is generated in the source chamber 100 and supplied to the growth chamber 111, and a nitrogen-containing gas is also supplied to the growth chamber 111, thereby growing the Group III nitride semiconductor substrate on the seed substrate 116.

The growth step further includes a reactive gas supply step, a Group III element oxide gas generation step, a Group III element oxide gas supply step, a nitrogen-containing gas supply step, a Group III nitride semiconductor substrate generation step, and a residual gas discharge step. Note that the steps included in the growth step may be performed simultaneously within the Group III nitride semiconductor substrate fabrication apparatus.

In the reactive gas supply step, a reactive gas is supplied to the source reaction chamber 101.

In the Group III element oxide gas generation step, a starting Group III element source is reacted with a reactive gas (a reducing gas if the starting Group III element source is an oxide, and an oxidizing gas if the starting Group III element source is a metal) to generate a Group III element oxide gas.

In the Group III element oxide gas supply step, the Group III element oxide gas produced in the Group III element oxide gas production step is supplied to the growth chamber 111.

In the nitrogen-containing gas supply step, a nitrogen-containing gas is supplied to the growth chamber 111.

In the Group III nitride semiconductor substrate generation step, the Group III element oxide gas supplied into the growth chamber 111 in the Group III element oxide gas supply step and the nitrogen-containing gas supplied into the growth chamber 111 in the nitrogen-containing gas supply step are reacted with each other to grow a Group III nitride semiconductor substrate on the seed substrate.

In the residual gas discharge step, unreacted gases not contributing to the fabrication of a Group III nitride semiconductor substrate are discharged to the outside of the chamber.

In a decomposition protection temperature-lowering step, the temperatures of the source chamber 100 and the growth chamber 111 are lowered to 500 °C while supplying NH₃ gas in order to suppress decomposition of the Group III nitride semiconductor substrate grown on the seed substrate 116.

In a temperature-lowering step, the temperatures of the source chamber 100 and the growth chamber 111 are lowered to below 100 °C in an inert gas atmosphere.

In an unloading step, the seed substrate 116 having the group III nitride substrate grown on the seed substrate 116 is unloaded from the growth chamber 111.

### <Overview of Group III Nitride Semiconductor Substrate Fabrication Apparatus>

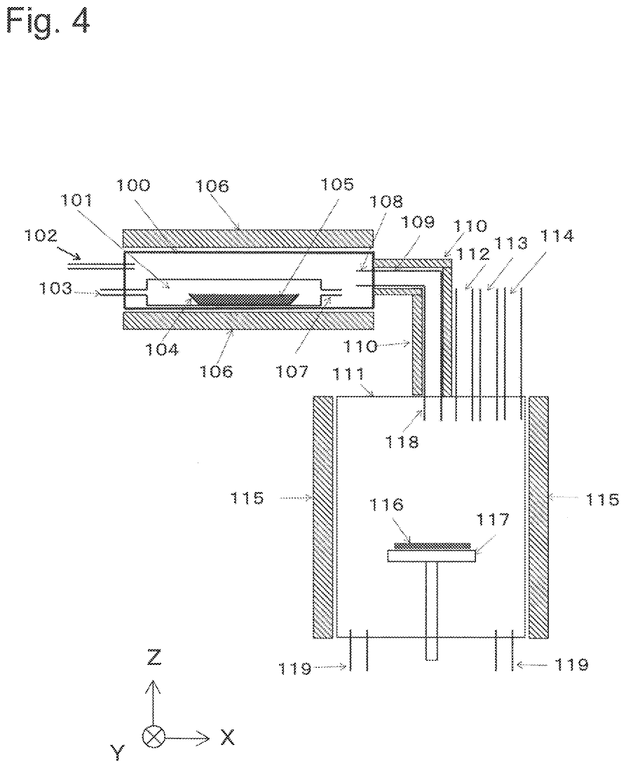

The overview of the fabrication apparatus used in the method for fabricating a Group III nitride semiconductor substrate constituting a Group III nitride semiconductor epitaxial wafer according to the first embodiment will be described with reference to FIG. 4. FIG. 4 is a schematic cross-sectional view of the fabrication apparatus for a Group III nitride semiconductor substrate constituting a Group III nitride semiconductor epitaxial wafer according to the first embodiment.

In FIG. 4, the size, ratio, etc. of each component may differ from the actual one. The apparatus for fabricating a Group III nitride semiconductor substrate has a source reaction chamber 101 disposed within the source chamber 100, and a source boat 104 carrying a starting Group III element source 105 disposed within the source reaction chamber 101. A reactive gas supply pipe 103 is connected to the source reaction chamber 101, supplying a gas that reacts with the starting Group III element source 105. The source reaction chamber 101 has a Group III element oxide gas discharge port 107 for discharging the generated Group III element oxide gas. When the starting Group III source is an oxide, a reducing gas is used as the reactive gas. When the starting Group III source is a metal, an oxidizing gas is used as the reactive gas. A first carrier gas supply port 102 for supplying a first carrier gas is connected to the source chamber 100, and the first carrier gas supplied from the first carrier gas supply port 102 and the Group III element oxide gas discharged from the Group III element oxide gas discharge port 107 flow from a gas discharge port 108 through a connection pipe 109 to the growth chamber 111, and are supplied into the growth chamber 111 from a gas supply port 118 connected to the growth chamber 111. The growth chamber 111 has the gas supply port 118, a third carrier gas supply port 112, a nitrogen-containing gas supply port 113, a second carrier gas supply port 114, and a discharge port 119. The growth chamber 111 includes the substrate susceptor 117 on which the seed substrate 116 is placed.

### <Details of Fabrication Method and Fabrication Apparatus>

The method for fabricating a group III nitride semiconductor substrate according to the first embodiment will be described in detail with reference to FIGS. 3A, 3B and 4.

In the first embodiment, metal Ga is used as the starting group III element source 105, but the present invention is not limited thereto, and for example, Al or In may also be used.

First, the seed substrate 116 is prepared. For example, gallium nitride, gallium arsenide, silicon, sapphire, silicon carbide, zinc oxide, gallium oxide, or ScAlMgO₄ can be used as the seed substrate 116. In the first embodiment, gallium nitride is used as the seed substrate 116.

The description will be given based on FIG. 3A.

In the temperature-raising step, the temperature of the growth chamber is raised in an inert gas atmosphere to a temperature not causing decomposition of the seed substrate 116. In the fabrication of a Group III nitride semiconductor substrate by the OVPE method, heating is performed in an inert gas (e.g., N₂ gas) atmosphere to approximately 500 °C.

In the decomposition protection temperature-raising step 1, the temperature is raised in a nitrogen-containing gas atmosphere while suppressing decomposition of the seed substrate 116. In the fabrication of a Group III nitride semiconductor substrate by the OVPE method, heating is performed in a state in which an inert gas and a nitrogen-containing gas, NH₃ gas, are mixed up to a temperature of 500 °C or higher but lower than 1100 °C. The reason for mixing NH₃ is to prevent decomposition of the seed substrate 116 due to desorption of N atoms. Heating may also be performed in a state in which H₂ gas is further mixed up.

In the decomposition protection temperature-raising step 2, the temperature is raised in an atmosphere of a Group III oxide gas and a nitrogen-containing gas while suppressing decomposition of the seed substrate 116. In the fabrication of a Group III nitride semiconductor substrate by the OVPE method, heating is performed up to a temperature of 1100 °C or higher but lower than 1500 °C in a state where H₂ gas, an inert gas, a Group III element oxide gas, and a nitrogen-containing gas NH₃ gas are mixed. The reason for mixing the Group III element oxide gas is that decomposition cannot be suppressed with a nitrogen-containing gas alone. By applying a driving force for the growth of the Group III nitride semiconductor substrate, it is possible to suppress decomposition.

In the growth step, a Group III element oxide gas is generated in the source chamber 100 and supplied to the growth chamber 111, and a nitrogen-containing gas is also supplied to the growth chamber 111 to grow a Group III nitride semiconductor substrate on the seed substrate 116. Specifically, the growth step includes the reactive gas supply step, the Group III element oxide gas generation step, the Group III element oxide gas supply step, the nitrogen-containing gas supply step, the Group III nitride semiconductor substrate generation step, and the residual gas discharge step.

Next, the description will be given based on FIG. 3B.

In the reactive gas supply step, a reactive gas is supplied from the reactive gas supply pipe 103 to the source reaction chamber 101 in the source chamber 100. As described above, the reactive gas may be a reducing gas or an oxidizing gas, as necessary. In the first embodiment, since metallic Ga is used as the starting Group III element source 105, H₂O gas is used as the reactive gas.

In the Group III element oxide gas generation step, the reactive gas supplied to the source reaction chamber 101 in the reactive gas supply step reacts with Ga, which is the starting Group III element source 105, to generate Ga₂O gas, which is a Group III element oxide gas. The generated Ga₂O gas is discharged from the source reaction chamber 101 to the source chamber 100 via the Group III element oxide gas discharge port 107. The discharged Ga₂O gas is mixed with a first carrier gas supplied to the source material chamber from the first carrier gas supply port 102, and supplied to the gas discharge port 108. In the first embodiment, the source chamber 100 is heated by a first heater 106. When the source chamber 100 is heated, the temperature of the source chamber 100 is preferably 800 °C or higher in view of the boiling point of Ga₂O gas. Furthermore, the temperature of the source chamber 100 is preferably set lower than that of the growth chamber 111. When the growth chamber is heated by a second heater 115 as described below, the temperature of the source chamber 100 is preferably set to, for example, less than 1800 °C. The starting Group III element source 105 is placed in the source boat 104 disposed in the source reaction chamber 101. The source boat 104 preferably has a shape that can increase the contact area between the reactive gas and the starting Group III element source. For example, the source boat 104 preferably may have a multi-tiered dish shape to prevent the starting Group III element source 105 and the reactive gas from passing through the source reaction chamber 101 without coming into contact with each other.

The Method for generating a Group III element oxide gas can be broadly divided into a method for reducing the starting Group III element source 105 and a method for oxidizing the starting Group III element source 105. For example, the reduction method uses an oxide (e.g., Ga₂O₃) as the starting Group III element source 105 and a reducing gas (e.g., H₂ gas, CO gas, CH₄ gas, C₂H₆ gas, H₂S gas, or SO₂ gas) as the reactive gas. On the other hand, the oxidation method uses a non-oxide (e.g., liquid Ga) as the starting Group III element source 105 and an oxidizing gas (e.g., H₂O gas, O₂ gas, CO gas, CO₂ gas, NO gas, N₂O gas, or NO₂ gas) as the reactive gas. In addition to the starting Group _{III} element source 105, an In source or an Al source can also be used as the starting Group III element. An inert gas, H₂ gas, or the like can be used as the first carrier gas.

In the Group III element oxide gas supply step, Ga₂O gas generated in the Group III element oxide gas generation step is supplied to the growth chamber 111 via the gas discharge port 108, the connection pipe 109, and the gas supply port 118. When the temperature of the connection pipe 109 connecting the source chamber 100 and the growth chamber 111 drops below the temperature of the source chamber 100, a reverse reaction of the reaction for generating the Group III element oxide gas occurs, and the starting Ga source 105 precipitates inside the connection pipe 109. Therefore, it is preferable that the connection pipe 109 be heated by a third heater 110 to a temperature higher than that of the first heater 106 so that the temperature does not drop below that of the source chamber 100.

In the nitrogen-containing gas supply step, a nitrogen-containing gas is supplied to the growth chamber 111 from the nitrogen-containing gas supply port 113. Examples of the nitrogen-containing gas include NH₃ gas, NO gas, NO₂ gas, N₂O gas, N₂H₂ gas, and N₂H₄ gas.

In the Group III nitride semiconductor substrate fabrication process, the source gases supplied into the growth chamber through each supply process are reacted to grow a Group III nitride semiconductor substrate on the seed substrate 116. The growth chamber 111 is preferably heated by the second heater 115 to a temperature at which the Group III element oxide gas and the nitrogen-containing gas react. At this time, the temperature of the growth chamber 111 is preferably controlled so as not to fall below the temperature of the source chamber 100, in order to prevent a reverse reaction of the reaction that produces the Group III element oxide gas. The temperature of the growth chamber 111 heated by the second heater 115 is preferably 1000 °C or higher and 1800 °C or lower. Furthermore, in order to suppress temperature fluctuations in the growth chamber 111 due to the Ga₂O gas produced in the source chamber 100 and the first carrier gas, it is desirable for the second heater 115 and the third heater 110 to have the same temperature.

The Group III element oxide gas supplied to the growth chamber 111 via the Group III element oxide supply step and the nitrogen-containing gas supplied to the growth chamber 111 via the nitrogen-containing gas supply step are mixed upstream of the seed substrate 116, whereby a Group III nitride semiconductor substrate can be grown on the seed substrate 116.

The reactive gas supply step, the Group III element oxide gas generation step, the Group III element oxide gas supply step, the nitrogen-containing gas supply step, the Group III nitride semiconductor substrate generation step, and the residual gas discharging step, which are included in the growth step, may be performed simultaneously.

The second carrier gas may be an inert gas, H₂ gas, or the like. The third carrier gas may be an inert gas, N₂ gas, Ar gas, He gas or the like.

In the residual gas exhaust process, the unreacted Group III element oxide gas and nitrogen-containing gas, as well as the first carrier gas, second carrier gas, and third carrier gas, are discharged from the discharge port 119.

In the decomposition protection temperature-lowering step, the temperature is lowered in a nitrogen-containing gas atmosphere while suppressing decomposition of the Group III nitride semiconductor substrate. In the fabrication of a Group III nitride semiconductor substrate by the OVPE method, the cooling is performed to 500 °C or lower in a state in which an inert gas and a nitrogen-containing gas, NH₃ gas, are mixed.

In the temperature-lowering step, the temperature is lowered in an inert gas atmosphere to a temperature at which the Group III nitride semiconductor substrate can be removed from the growth chamber.

In the first embodiment, the seed substrate 116 on which the group III nitride semiconductor substrate has been grown is removed from the growth chamber 111 after the temperature-lowering step.

Thus, a group III nitride semiconductor substrate can be obtained.

### <First Group III Nitride Semiconductor Film>

The first Group III nitride semiconductor film is obtained by epitaxially growing a Group III nitride semiconductor film containing Al and Ga as Group III elements on a Group III nitride semiconductor substrate. The step of epitaxially growing the first Group III nitride semiconductor film may be performed based on OVPE in the above-described apparatus and method for fabricating a Group III nitride semiconductor substrate, by replacing the seed substrate with a Group III nitride semiconductor substrate and substituting one containing Al and Ga as the starting Group III element source. This allows the first Group III nitride semiconductor film to be epitaxially grown on the Group III nitride semiconductor substrate without removing it from the growth chamber after the Group III nitride semiconductor substrate is fabricated. The fabrication method of the first Group III nitride semiconductor film is not limited to the fabrication method based on the OVPE method, and other fabrication methods may be used, such as a HVPE (Hydride Vapor Phase Epitaxy) method or a MOCVD (Metal-Organic Chemical Vapor Deposition) method using trimethylgallium (TMG) or triethylgallium (TEG) as a Ga source, trimethylaluminum (TMA) as an Al source, and ammonia (NH₃) as a nitrogen (N) source.

### <Second to Nth Group III Nitride Semiconductor Films>

The second through Nth Group III nitride semiconductor films are obtained by epitaxially growing one or more Group III nitride semiconductor films on a first Group III nitride semiconductor film sequentially. The step of epitaxially growing the second through Nth Group III nitride semiconductor films may be performed based on OVPE method by replacing the seed substrate with a first Group III nitride semiconductor substrate in the above-described apparatus and method for fabricating a Group III nitride semiconductor substrate. In this way, after the first Group III nitride semiconductor film is fabricated, the second through Nth Group III nitride semiconductor films can be epitaxially grown continuously and sequentially above the first Group III nitride semiconductor film without removing the substrate from the growth chamber. The fabrication method of the second to Nth Group III nitride semiconductor films is not limited to the fabrication method based on the OVPE method, and other fabrication methods may be used, such as the HVPE (Hydride Vapor Phase Epitaxy) method or the MOCVD (Metal-Organic Chemical Vapor Deposition) method using trimethylgallium (TMG) or triethylgallium (TEG) as a Ga source, trimethylaluminum (TMA) as an Al source, and ammonia (NH₃) as a nitrogen (N) source.

Thus, a Group III nitride semiconductor epitaxial wafer can be obtained.

### Examples 1 to 3: Group III Nitride Semiconductor Substrates Formed by HVPE Method

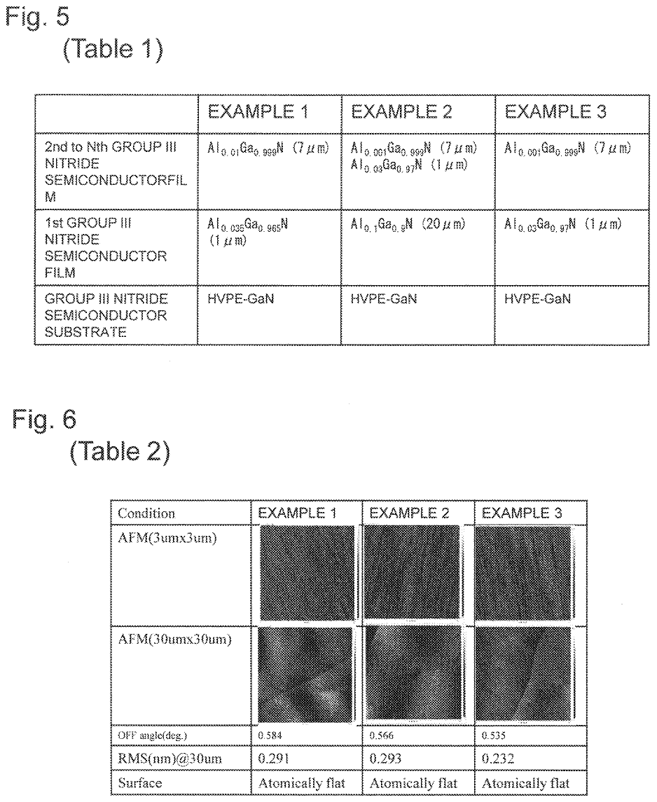

FIG. 5 is Table 1 showing the composition of each layer of Group III nitride semiconductor epitaxial wafers according to Examples 1 to 3, in which first to Nth Group III nitride semiconductor films are epitaxially grown above a Group III nitride semiconductor substrate formed by HVPE method. FIG. 6 is Table 2 showing AFM images of a 3-μm square area of the surface of the Group III nitride semiconductor epitaxial wafers according to Examples 1 to 3, and AFM images of a 30-μm square area of the surface, as well as the off-angles and root-mean-square roughness (RMS) values of the Group III nitride semiconductor epitaxial wafers.

In the Group III nitride semiconductor epitaxial wafers according to Examples 1 to 3, the Group III nitride semiconductor substrate is GaN formed by HVPE method, as shown in FIG. 5. In Examples 1 and 3, first and second Group III nitride semiconductor films are provided, and in Example 2, first to third Group III nitride semiconductor films are provided.

As shown in FIG. 6, in Examples 1 to 3, the root mean square RMS roughness value was 1 nm or less, and the surface had sufficient flatness.

### Examples 4 to 6: Group III Nitride Semiconductor Substrates Formed by OVPE Method

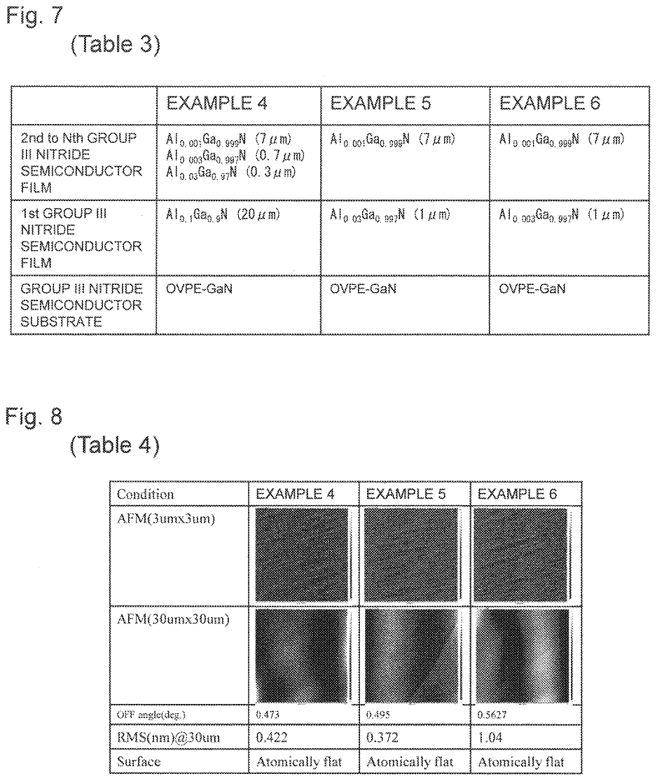

FIG. 7 is Table 3 showing the composition of each layer of Group III nitride semiconductor epitaxial wafers according to Examples 4 to 6, in which first to Nth Group III nitride semiconductor films were epitaxially grown above a Group III nitride semiconductor substrate formed by OVPE method. FIG. 8 is Table 4 showing AFM images of a 3 μm square area of the surface of the Group III nitride semiconductor epitaxial wafers according to Examples 4 to 6, AFM images of a 30 μm square area of the surface, and the off-angles and root-mean-square (RMS) roughness values of the Group III nitride semiconductor epitaxial wafers.

In the Group III nitride semiconductor epitaxial wafers according to Examples 4 to 6, the Group III nitride semiconductor substrate is GaN formed by OVPE method, as shown in FIG. 7. In Example 4, first to fourth Group III nitride semiconductor films are provided, and in Examples 5 and 6, first and second Group III nitride semiconductor films are provided.

As shown in FIG. 8, in Examples 4 to 6, the root-mean-square (RMS) roughness value was 1 nm or less, and the surface had sufficient flatness.

<When Al Composition Ratio relative to All Group III Elements in Group III Nitride Semiconductor Film Is Uniform in Thickness Direction>

### Example 7

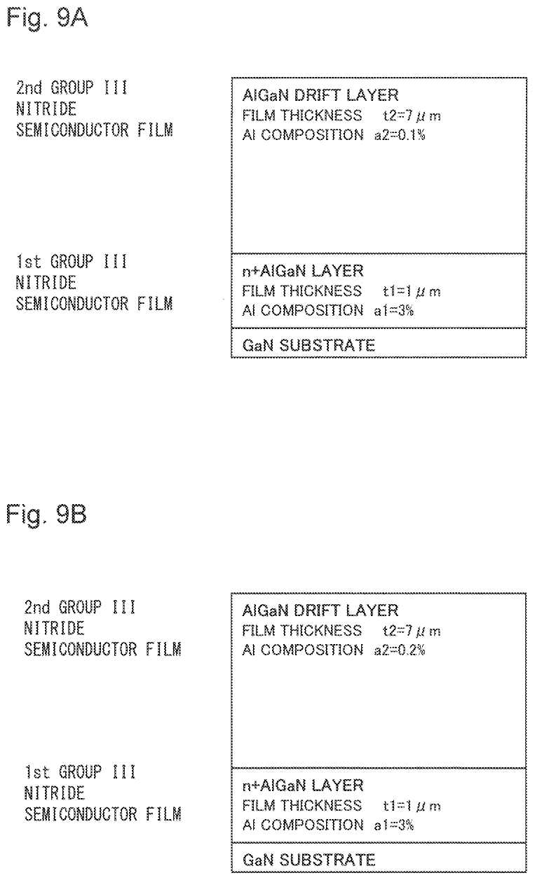

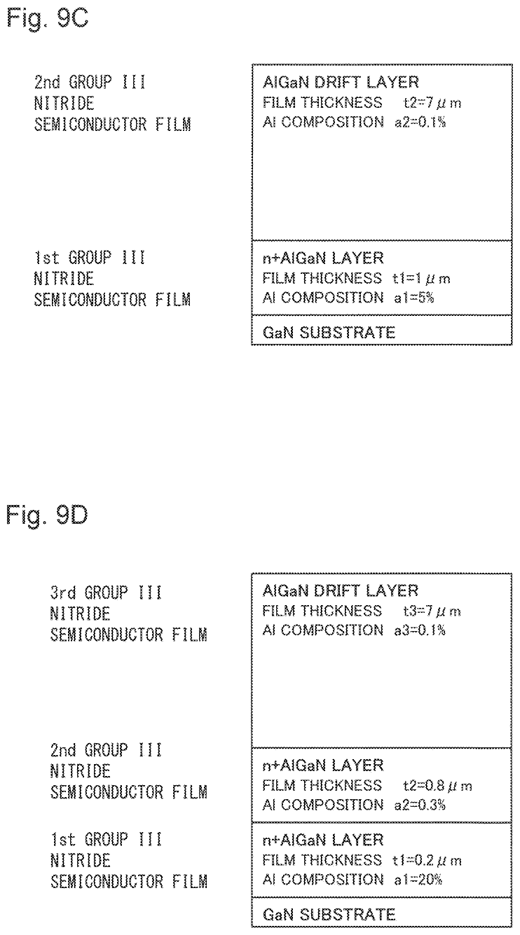

FIG. 9A is a schematic cross-sectional view showing the Al composition ratio and thickness of each layer of a group III nitride semiconductor epitaxial wafer according to Example 7.

As shown in FIG. 9A, the first Group III nitride semiconductor film has a thickness t₁ of 1 μm and an Al composition ratio a₁ of 3 atom %, and the second Group III nitride semiconductor film has a thickness t₂ of 7 μm and an Al composition ratio a₂ of 0.1 atom %.

The relational expression including the sum of the warp amounts of the first and second Group III nitride semiconductor films is:

t₁*a₁+t₂*a₂=(1 μm)*(3atom %)+(7 μm)*(0.1atom %)=3.7<6

This satisfies the above formula (8), and it is understood that the amount of warp can be suppressed to be equal to or less than the upper limit.

### Example 8

FIG. 9B is a schematic cross-sectional view showing the Al composition ratio and thickness of each layer of a group III nitride semiconductor epitaxial wafer according to Example 8.

As shown in FIG. 9B, the first Group III nitride semiconductor film has a thickness t₁ of 1 μm and an Al composition ratio a₁ of 3 atom %, and the second Group III nitride semiconductor film has a thickness t₂ of 7 μm and an Al composition ratio a₂ of 0.2 atom %.

The relational expression including the sum of the warp amounts of the first and second Group III nitride semiconductor films is:

t₁*a₁+t₂*a₂−(1 μm)*(3atom %)+(7 μm)*(0.2atom %)=4.4<6

This satisfies the above formula (8), and it is understood that the amount of warp can be suppressed to be equal to or less than the upper limit.

### Example 9

FIG. 9C is a schematic cross-sectional view showing the Al composition ratio and thickness of each layer of a group III nitride semiconductor epitaxial wafer according to Example 9.

As shown in FIG. 9C, the first Group III nitride semiconductor film has a thickness t₁ of 1 μm and an Al composition ratio a₁ of 5 atom %, and the second Group III nitride semiconductor film has a thickness t₂ of 7 μm and an Al composition ratio a₂ of 0.1 atom %.

The relational expression including the sum of the warp amounts of the first and second Group III nitride semiconductor films is:

t₁*a₁+t₂*a₂−(1 μm)*(5atom %)+(7 μm)*(0.1atom %)=5.7<6

This satisfies the above formula (8), and it is understood that the amount of warp can be suppressed to be equal to or less than the upper limit.

### Example 10

FIG. 9D is a schematic cross-sectional view showing the Al composition ratio and thickness of each layer of a group III nitride semiconductor epitaxial wafer according to Example 10.

As shown in FIG. 9D, the first Group III nitride semiconductor film has a thickness t₁ of 0.2 μm and an Al composition ratio a₁ of 20 atom %, the second Group III nitride semiconductor film has a thickness t₂ of 0.8 μm and an Al composition ratio a₂ of 0.3 atom %, and the third Group III nitride semiconductor film has a thickness t₃ of 7 μm and an Al composition ratio a₃ of 0.1 atom %.

The relational expression including the sum of the amounts of warp of the first to third Group III nitride semiconductor films is:

t₁*a₁+t₂*a₂+t₃*a₃=(0.2 μm)*(20atom %)+(0.8 μm)*(0.3atom %)+(7 μm)*(0.1atom %)=4.94<6

This satisfies the above formula (8), and it is understood that the amount of warp can be suppressed to be equal to or less than the upper limit.

<When Al composition Ratio in Group III Nitride Semiconductor Film Varies in Thickness Direction>

When the Al composition ratio in the group III nitride semiconductor film varies in the thickness direction, the above formula (8) can be transformed as follows:

$$6 \geq {\sum }_{i = 1}^{N} {\int }_{0}^{{t}_{i}} {a}_{i} ( t ) dt \geq 0 \qquad ( 9 )$$

### Example 11

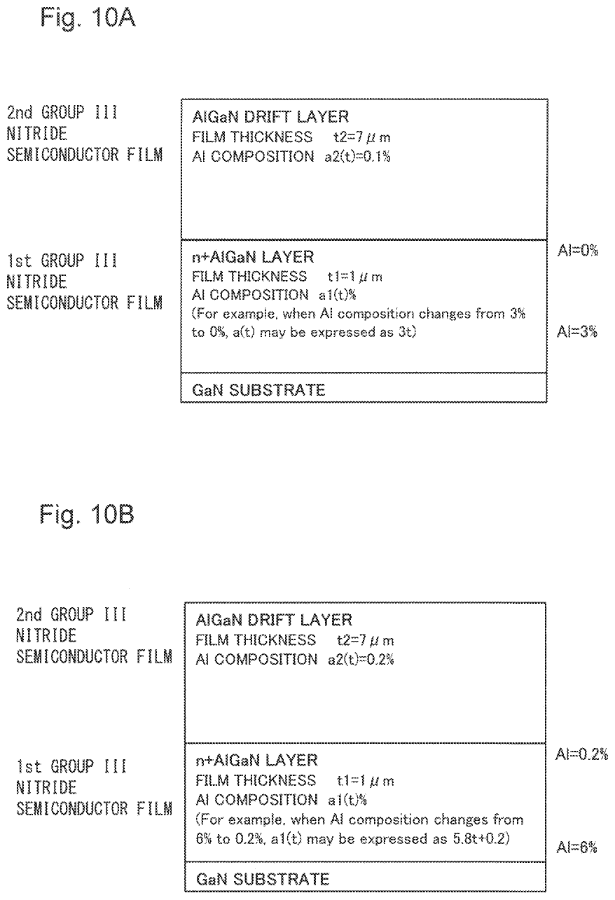

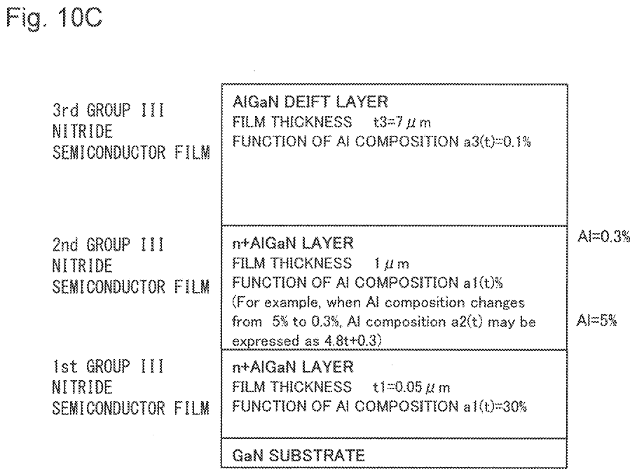

FIG. 10A is a schematic cross-sectional view showing the Al composition ratio and thickness of each layer of a group III nitride semiconductor epitaxial wafer according to Example 11.

As shown in FIG. 10A, the thickness t₁ of the first Group III nitride semiconductor film is 1 μm, and the Al composition ratio aᵢ varies linearly from 3 atom % to 0 atom % along the thickness direction, while the thickness t₂ of the second Group III nitride semiconductor film is 7 μm, and the Al composition ratio a₂ is 0.1 atom % (constant).

The relational expression including the sum of the warp amounts of the first and second Group III nitride semiconductor films is:

$${\sum }_{i = 1}^{N} {\int }_{0}^{{t}_{i}} {a}_{i} ( t ) dt = {\int }_{0}^{1} {a}_{1} ( t ) dt + {\int }_{0}^{7} {a}_{2} ( t ) dt = {\int }_{0}^{1} 3 tdt + {\int }_{0}^{7} ( 0.1 ) dt = \frac{3}{2} \times {1}^{2} + 0.1 \times 7 = 2.2 < 6$$

This satisfies the above formula (9), and it is understood that the amount of warp can be suppressed to be equal to or less than the upper limit.

FIG. 10B is a schematic cross-sectional view showing the Al composition ratio and thickness of each layer of a group III nitride semiconductor epitaxial wafer according to Example 12.

The thickness t₁ of the first Group III nitride semiconductor film is 1 μm, and the Al composition ratio a₁ varies linearly from 6 atom % to 0.2 atom % (5.8t+0.2) along the thickness direction, while the thickness t₂ of the second Group III nitride semiconductor film is 7 μm, and the Al composition ratio a₂ is 0.2 atom % (constant).

The relational expression including the sum of the warp amounts of the first and second Group III nitride semiconductor films is:

$${\sum }_{i = 1}^{N} {\int }_{0}^{{t}_{i}} {a}_{i} ( t ) dt = {\int }_{0}^{1} {a}_{1} ( t ) dt + {\int }_{0}^{7} {a}_{2} ( t ) dt = {\int }_{0}^{1} ( 5.8 t + 0.2 ) dt + {\int }_{0}^{7} ( 0.2 ) dt = \frac{5.8}{2} \times {1}^{2} + 0.2 \times 1 + 0.2 \times 7 = 4.5 < 6$$

This satisfies the above formula (9), and it is understood that the amount of warp can be suppressed to be equal to or less than the upper limit.

### Example 13

FIG. 10C is a schematic cross-sectional view showing the Al composition ratio and thickness of each layer of a group III nitride semiconductor epitaxial wafer according to Example 13.

As shown in FIG. 10C, the first Group III nitride semiconductor film has a thickness t₁ of 0.05 μm and an Al composition ratio aᵢ of 30 atom % (constant), the second Group III nitride semiconductor film has a thickness t₂ of 1 μm and an Al composition ratio a₂ that varies linearly from 5 atom % to 0.3 atom % along the thickness direction (4.7t+0.3), and the third Group III nitride semiconductor film has a thickness t₃ of 7 μm and an Al composition ratio a₂ of 0.1 atom % (constant).

The relational expression including the sum of the amounts of warp of the first to third Group III nitride semiconductor films is:

$${\sum }_{i = 1}^{N} {\int }_{0}^{{t}_{i}} {a}_{i} ( t ) dt = {\int }_{0}^{0.05} {a}_{1} ( t ) dt + {\int }_{0}^{1} {a}_{2} ( t ) dt + {\int }_{0}^{7} {a}_{3} ( t ) dt = {\int }_{0}^{0.05} 30 dt + {\int }_{0}^{1} ( 4.7 t + 0.3 ) dt + {\int }_{0}^{7} ( 0.1 ) dt = 30 \times 0.05 + \frac{4.7}{2} \times {1}^{2} + 0.3 \times 1 + 0.1 \times 7 = 1.5 + 2.35 + 0.3 + 0.7 = 4.55 < 6$$

This satisfies the above formula (9), and it is understood that the amount of warp can be suppressed to be equal to or less than the upper limit.

According to the Group III nitride semiconductor epitaxial wafer of the present disclosure, the flatness of the top surface of the Group III nitride semiconductor film can be ensured by providing, as an intermediate layer, a first Group III nitride semiconductor film containing Al and Ga as Group III elements. Furthermore, by controlling the thickness and Al composition ratio relative to all Group III elements in the Group III nitride semiconductor film at their respective upper limits, the amount of warp can be adjusted to be equal to or less than the upper limit.

### REFERENCE SIGNS LIST

2 Group III nitride semiconductor substrate
4 First Group III nitride semiconductor film
6 Second Group III nitride semiconductor film
10 Group III nitride semiconductor epitaxial wafer
100 Source chamber
101 Source reaction chamber
102 First carrier gas supply port
103 Reactive gas supply pipe
104 Source boat
105 Starting Group III element source
106 First heater
107 Group III element oxide gas discharge port
108 Gas discharge port
109 Connection pipe
110 Third heater
111 Growth chamber
112 Third carrier gas supply port
113 Nitrogen-containing gas supply port
114 Second carrier gas supply port
115 Second heater
116 Seed substrate
117 Substrate susceptor
118 Gas supply port
119 Discharge port

What is claimed is:

1. A Group III nitride semiconductor epitaxial wafer comprising:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation,
$${C}_{E} = α Φ {\sum }_{i = 1}^{N} ( {t}_{i} {a}_{i} ) \geq 0$$
where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation
$${C}_{L} \geq {C}_{S} + {C}_{E} = {C}_{S} + α Φ {\sum }_{i = 1}^{N} ( {t}_{i} {a}_{i} ) \geq 0$$
is satisfied.

2. A Group III nitride semiconductor epitaxial wafer comprising:
a Group III nitride semiconductor substrate exhibiting N-type conductivity;
a first Group III nitride semiconductor film epitaxially grown on the Group III nitride semiconductor substrate, the first Group III nitride semiconductor film containing Al and Ga as Group III elements; and
second to Nth Group III nitride semiconductor films epitaxially grown above the first Group III nitride semiconductor film, where Nis a natural number equal to or greater than 2, wherein when the sum of the warp amounts of the first to Nth Group III nitride semiconductor films with the downward convex direction as the positive direction is defined as C_{E} (μm), the sum of the warp amounts C_{E} (μm) is expressed as following equation,
$${C}_{E} = α Φ {\sum }_{i = 1}^{N} {\int }_{0}^{{t}_{i}} {a}_{i} ( t ) dt$$
where i is a natural number from 1 to N; the thickness of the i-th Group III nitride semiconductor film is tᵢ (μm); Al composition ratio relative to all Group III elements in the i-th Group III nitride semiconductor film having a thickness t varies in the range of thickness 0 (μm) to thickness tᵢ (μm) along the thickness direction of the i-th Group III nitride semiconductor film, the function of Al composition ratio is expressed as aᵢ(t) (atom %) with thickness t as a variable; the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), following equation
$${C}_{L} \geq {C}_{S} + {C}_{E} = {C}_{S} + α Φ {\sum }_{1}^{N} {\int }_{0}^{ti} {a}_{i} ( i ) dt \geq 0$$
is satisfied.

3. The Group III nitride semiconductor epitaxial wafer according to claim 1, wherein the first Group III nitride semiconductor film has an Al composition ratio of 0.1 atom % or more in the first Group III nitride semiconductor film.

4. The Group III nitride semiconductor epitaxial wafer according to claim 1, wherein the Group III nitride semiconductor substrate has a carrier concentration of 10¹⁷ cm⁻³ or more and 10¹⁹ cm⁻³ or less.

5. The Group III nitride semiconductor epitaxial wafer according to claim 1, wherein the Group III nitride semiconductor substrate has a carrier concentration of 1020 cm⁻³ or more, and
wherein the dopant element is oxygen.

6. The Group III nitride semiconductor epitaxial wafer according to claim 1, wherein the first Group III nitride semiconductor film has a carrier concentration of 10¹⁷ cm⁻³ or more.

7. The Group III nitride semiconductor epitaxial wafer according to claim 1, wherein an i-th Group III nitride semiconductor film, where i is 2 or more, epitaxially grown above the first Group III nitride semiconductor film has a carrier concentration of 10¹⁷ cm⁻³ or less.

8. The Group III nitride semiconductor epitaxial wafer according to claim 1, wherein the first Group III nitride semiconductor film has a carrier concentration of 10¹⁷ cm⁻³ or more, and
wherein an i-th Group III nitride semiconductor film, where i is 2 or more, epitaxially grown above the first Group III nitride semiconductor film has a carrier concentration of 10¹⁷ cm⁻³ or less.

9. An electronic device using the Group III nitride semiconductor epitaxial wafer according to claim 1.

10. A method for fabricating a Group III nitride semiconductor epitaxial wafer, comprising:
providing a Group III nitride semiconductor substrate exhibiting N-type conductivity;
epitaxially growing a first Group III nitride semiconductor film containing Al and Ga as Group III elements on the Group III nitride semiconductor substrate; and
epitaxially growing second to Nth Group III nitride semiconductor films on the first Group III nitride semiconductor film, where Nis a natural number equal to or greater than 2,
wherein when the sum of the warp amounts of the first to Nth Group III nitride semiconductor films with the downward convex direction as the positive direction is defined as C_{E} (μm), the sum of the warp amounts C_{E} (μm) is expressed as following equation
$${C}_{E} = α Φ {\sum }_{i = 1}^{N} ( {t}_{i} {a}_{i} ) \geq 0$$
where i is a natural number from 1 to N; the thickness of the i-th Group III nitride semiconductor film is tᵢ (μm); the Al composition ratio relative to all Group III elements in the i-th Group III nitride semiconductor film is aᵢ(atom %); the diameter of the Group III nitride semiconductor epitaxial wafer is Φ (cm), and the correction coefficient is α, and
wherein when the warp amount of the Group III nitride semiconductor substrate with the downward convex direction as the positive direction is defined as C_{S} (μm) and when the upper limit of warp amount of the Group III nitride semiconductor epitaxial wafer is defined as C_{L} (μm), the first to Nth Group III nitride semiconductor films are epitaxially grown so as to satisfy following equation.
$${C}_{L} \geq {C}_{S} + {C}_{E} = {C}_{S} + α Φ {\sum }_{i = 1}^{N} ( {t}_{i} {a}_{i} ) \geq 0$$
